(19) United States
(12) Patent Application Publication
(10) Pub. No.: US 2022/0282934 A1
(43) Pub. Date: Sep. 8, 2022

(54) HEAT PIPE

(71) Applicant: MITSUBISHI HEAVY INDUSTRIES, LTD., Tokyo (JP)

(72) Inventors: Nobuhide HARA, Tokyo (JP); Masafumi KATTA, Tokyo (JP); Koichi TANIMOTO, Tokyo (JP); Yuichi OTANI, Tokyo (JP)

(21) Appl. No.: 17/583,538

(22) Filed: Jan. 25, 2022

(30) Foreign Application Priority Data
Mar. 5, 2021 (JP) 2021-035233

(51) Int. Cl. F28D 15/02; F28D 15/04; H05K 7/20

(52) U.S. Cl. CPC F28D 15/0233; F28D 15/04; H05K 7/20336

(57) ABSTRACT

A heat pipe includes an external cylinder extending in an axial direction, an internal cylinder provided inside the external cylinder so as to extend in the axial direction, and a wick provided between and integrally with the external cylinder and the internal cylinder. The wick includes a plurality of micro through portions extending linearly in the axial direction. According to this configuration, a working fluid moves smoothly in the axial direction without being blocked, and thus it is possible to provide a heat pipe having a further improved heat exchange performance.

### CROSS-REFERENCE TO RELATED APPLICATIONS

This application claims the benefit of priority to Japanese Patent Application Number 2021-035233 filed on Mar. 5, 2021. The entire contents of the above-identified application are hereby incorporated by reference.

### TECHNICAL FIELD

The disclosure relates to a heat pipe.

### RELATED ART

As a device for transporting heat in a given direction, the use of a heat pipe is being promoted. As described in JP 2017-146024 A, a general heat pipe mainly includes an external cylinder having a cylindrical shape, an internal cylinder provided on the inner circumferential side of the external cylinder, and a wick packed between the external cylinder and the internal cylinder. The wick has a mesh shape formed by weaving fine wires, for example. Capillary action caused in a micro flow path formed inside the wick allows a working fluid such as water or alcohol to move in the micro flow path as a liquid.

For example, a case where the heat pipe is disposed between a heat source side and a low temperature heat source side will be considered. In that case, heat exchange occurs between the heat source and a working fluid inside the heat pipe. The gas (steam) generated by the heat exchange on the heat source side of the heat pipe exchanges heat with the low temperature heat source provided on a heat dissipation side. The heat exchange with the low temperature heat source causes the steam to be condensed into a liquid, and the liquid moves again to the heat source side inside the heat pipe through the micro flow path of the wick. Continuous generation of the above cycle allows heat transport between the heat source side and the low temperature heat source side.

### SUMMARY

However, when the wick is formed of a mesh-shaped member as described above, the cross-sectional area of the micro flow path is blocked by wires when viewed from the flow direction of the working fluid (that is, a heat transport direction). Specifically, the cross-sectional area of the flow path is reduced by wires woven in a direction crossing the flow path. As a result, transfer of the working fluid by a capillary force is restricted, and the heat exchange performance of the heat pipe may be affected.

The present disclosure has been made to solve the above problems, and an object of the present disclosure is to provide a heat pipe having a further improved heat exchange performance.

In order to solve the above-described problems, a heat pipe according to the present disclosure includes an external cylinder extending in a direction of an axis line, an internal cylinder provided inside the external cylinder so as to extend in the direction of the axis line, and a wick provided between and integrally with the external cylinder and the internal cylinder, the wick including a plurality of micro through portions extending linearly in the direction of the axis line.

A heat pipe according to the present disclosure includes an external cylinder extending in a direction of an axis line, and a wick being integrally provided on an inside surface of the external cylinder inside the external cylinder, the wick forming a gas passage flow path extending through along the axis line on an inner circumferential side. The wick includes a gas-liquid passage portion having a void ratio increasing from an outer side toward an inner side in a radial direction of the axis line.

According to the present disclosure, a heat pipe having a further improved heat exchange performance can be provided.

### BRIEF DESCRIPTION OF DRAWINGS

The disclosure will be described with reference to the accompanying drawings, wherein like numbers reference like elements.

FIG. 1 is a vertical cross-sectional view of a heat pipe according to a first embodiment of the present disclosure.

FIG. 2 is a cross-sectional view as seen from an axial direction of a heat pipe according to a first embodiment of the present disclosure.

FIG. 3 is a perspective view illustrating an example of a three dimensional structure of a wick according to a first embodiment of the present disclosure.

FIG. 4 is a vertical cross-sectional view of a heat pipe according to a second embodiment of the present disclosure.

FIG. 5 is a cross-sectional view taken along the line V-V in FIG. 4.

FIG. 6 is a cross-sectional view as seen from an axial direction of a modification example of a heat pipe according to a second embodiment of the present disclosure.

FIG. 7 is a vertical cross-sectional view of a heat pipe according to a third embodiment of the present disclosure.

FIG. 8 is a vertical cross-sectional view of a heat pipe according to a fourth embodiment of the present disclosure.

FIG. 9 is a cross-sectional view as seen from an axial direction of a heat pipe according to a fourth embodiment of the present disclosure.

FIG. 10 is a cross-sectional view illustrating an example in which a wick according to each of the embodiments of the present disclosure is used for cooling a die-casting mold.

### DESCRIPTION OF EMBODIMENTS

### First Embodiment

### Configuration of Heat Pipe

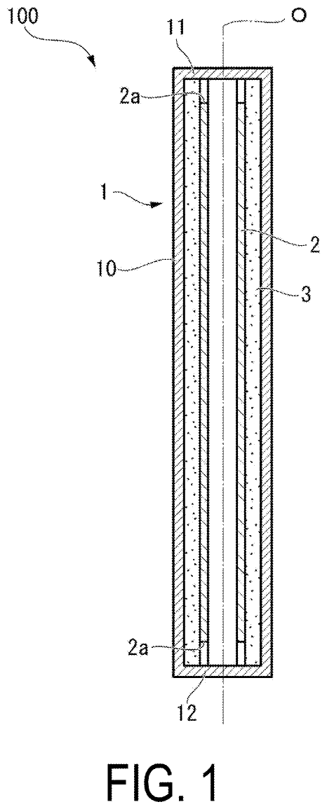

Hereinafter, a heat pipe 100 according to a first embodiment of the present disclosure will be described with reference to FIGS. 1 to 3. The heat pipe 100 is a device for transporting heat in a given direction. As illustrated in FIG. 1, the heat pipe 100 includes an external cylinder 1, an internal cylinder 2, and a wick 3.

### Configuration of External Cylinder

The external cylinder 1 has a bottomed cylindrical shape extending along an axis O. More specifically, the external cylinder 1 includes an external cylinder main body 10 having a cylindrical shape centered around the axis O, a first lid body 11 which closes an end portion of the external cylinder main body 10 on one side in the axis O direction, and a second lid body 12 which closes an end portion on an other side in the axis O direction.

### Configuration of Internal Cylinder

The internal cylinder 2 is provided on the inner side of the external cylinder 1 and has a cylindrical shape extending along the axis O. The internal cylinder 2 is preferably provided coaxially with the external cylinder 1. The dimension of the internal cylinder 2 in the axis O direction is set to be smaller than the dimension of the external cylinder 1. Specifically, an end portion of the internal cylinder 2 on one side in the axis O direction is positioned closer to an other side than an end portion of the external cylinder 1 on the one side in the axis O direction. Further, an end portion of the internal cylinder 2 on the other side in the axis O direction is positioned closer to the one side than an end portion of the external cylinder 1 on the other side in the axis O direction. Consequently, an opening 2a expanding in a radial direction with respect to the axis O is formed at both end portions of the internal cylinder 2 in the axis O direction. Note that the opening 2a may be formed over the whole region in the circumferential direction or may be formed only in a partial region in the circumferential direction of the internal cylinder 2.

### Configuration of Wick

The wick 3 is provided between the external cylinder 1 and the internal cylinder 2. More specifically, the wick 3 is packed between the inside surface 13 of the external cylinder 1 and the outside surface 21 of the internal cylinder 2. The external cylinder 1, the internal cylinder 2, and the wick 3 are formed of the same material integrally with each other by 3D additive manufacturing including, for example, an additive modeling method (AM method). Note that only the wick 3 can be formed by extrusion molding.

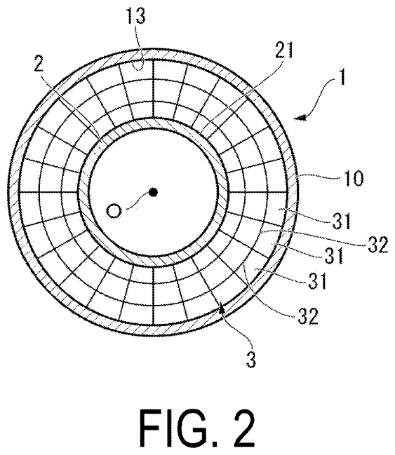

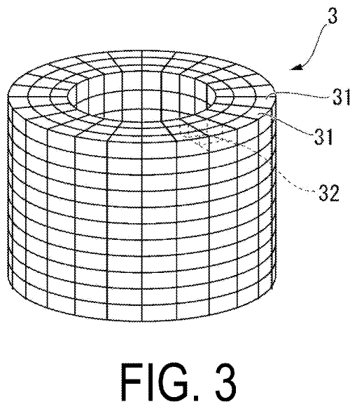

As illustrated in FIGS. 2 and 3, the wick 3 has a three dimensional lattice shape as a whole. Consequently, in the wick 3, there are formed a plurality of micro through portions 31 linearly extending in the axis O direction, and a communicating portion 32 for enabling communication between the micro through portions 31 adjacent to each other in the radial direction and the circumferential direction. The micro through portion 31 is a flow path linearly extending through without being blocked in the axis O direction when viewed from the axis O direction. The plurality of micro through portions 31 are formed adjacent to each other in the circumferential direction and in the radial direction. The communicating portion 32 is a flow path which is inevitably formed because the wick 3 has a lattice shape.

That is, inside the wick 3, the working fluid (alcohol or water) can move in the axis O direction, the radial direction, and the circumferential direction. The micro through portion 31 and the communicating portion 32 preferably have a lattice length of about 1000 μm. Consequently, capillary action for the working fluid is generated in the micro through portion 31 and the communicating portion 32. In other words, as long as a capillary force is generated, the dimensions of the micro through portion 31 and the communicating portion 32 may be appropriately set.

### Operational Effects

To operate the heat pipe 100, first, the heat pipe 100 is filled with water or alcohol as a working fluid. Then, a heat source is brought close to an end portion on one side in the axis O direction, and a low temperature heat source (or cooling medium) is brought close to an end portion on the other side.

At this time, heat exchange occurs between the heat source and the working fluid inside the heat pipe 100. The gas (steam) generated by the heat exchange on the heat source side of the heat pipe 100 (that is, the side of the first lid body 11) flows through the inside of the internal cylinder 2 to a heat dissipation side (that is, to the side of the second lid body 12). Here, the working fluid exchanges heat with the low temperature heat source provided on the heat dissipation side. The heat exchange with the low temperature heat source causes the steam to be condensed into a liquid, and the liquid moves again to the heat source side in the heat pipe 100 through the micro through portions 31 in the wick 3. Continuous generation of the above cycle allows heat transport between the heat source side and the low temperature heat source side.

However, in contrast to the above configuration, when the wick 3 is formed of a mesh-shaped member made of woven wires, the cross-sectional area of the micro flow path is blocked by wires when viewed from the flow direction of the working fluid (that is, a heat transport direction). Specifically, the cross-sectional area of the flow path is reduced by wires woven in a direction crossing the flow path. As a result, transfer of the working fluid by a capillary force is restricted, and the heat exchange performance of the heat pipe 100 may be affected.

For this reason, in the present embodiment, the configuration of the wick 3 as described above is adopted. According to the above configuration, the micro through portion 31 extends linearly in the axis O direction. That is, there is no obstruction blocking the working fluid in the micro through portion 31 from the axis O direction. Accordingly, the flow of the working fluid in the axis O direction can be generated more smoothly. As a result, the heat exchange performance of the heat pipe 100 can be improved.

Further, according to the above configuration, the working fluid can move in the radial direction and the circumferential direction between the micro through portions 31 through the communicating portion 32. This allows the distribution of the working fluid in a cross section orthogonal to the axis O to be homogenized. In other words, the working fluid does not concentrate in some regions only. Consequently, the flow rate of the working fluid can be ensured throughout the cross-sectional area of the wick 3. Thus, the heat exchange performance of the heat pipe 100 can be further improved.

Furthermore, according to the above configuration, the plurality of micro through portions 31 are arranged in the radial direction. Thus, the cross-sectional area of the flow path of the working fluid can be further increased. Therefore, the flow rate of the working fluid per unit area is increased, and the heat exchange performance of the heat pipe 100 can be further improved.

The first embodiment of the present disclosure has been described above. Note that various changes and modifications can be made to the above-described configurations without departing from the gist of the present disclosure. For example, in the first embodiment described above, an example in which the plurality of micro through portions 31 of the wick 3 are arranged in the radial direction has been described. However, depending on the constraints and the dimensional conditions of a space in which the heat pipe 100 is used, it is possible to provide only one micro through portion 31 (only one layer) in the radial direction.

### Second Embodiment

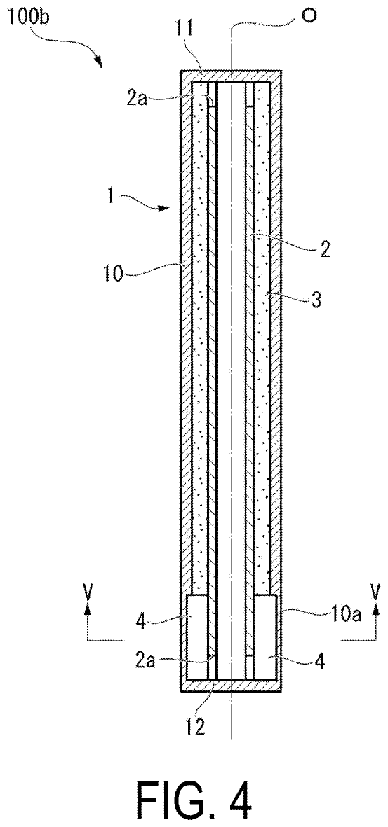

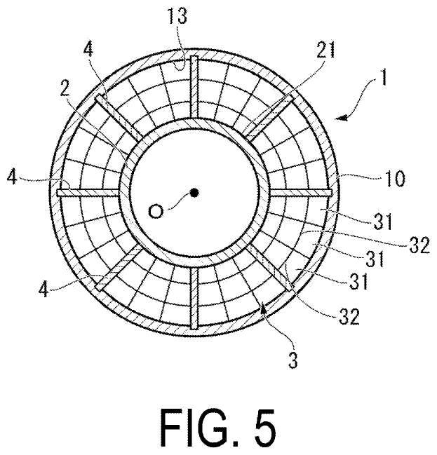

Next, a heat pipe 100b according to a second embodiment of the present disclosure will be described with reference to FIGS. 4 and 5. Note that the same components as those of the first embodiment will be denoted by the same reference signs, and a detailed description thereof will be omitted. As illustrated in FIG. 4 or 5, the heat pipe 100b according to the present embodiment further includes a fin 4.

Specifically, the fin 4 is provided at the end portion on the other side in the axis O direction (that is, the end portion on the side where the low temperature heat source is located as described in the first embodiment). The fin 4 protrudes from the external cylinder 1 toward the internal cylinder 2 in the radial direction, and a plurality of the fins 4 are arranged at intervals in the circumferential direction. In addition, a portion where the fin 4 is provided is a thin wall portion 10a whose wall thickness is set to be smaller than other portions of the external cylinder main body 10. Specifically, at this portion, an annular groove recessed outward in the radial direction is formed on the inside surface of the external cylinder main body 10 to form the thin wall portion 10a. The fins 4 are arranged along the inside surface of the thin wall portion 10a.

According to the above configuration, by forming the thin wall portion 10a, the thermal resistance between the working fluid and the outside can be made smaller than that of other portions. Further, a large area of contact with the working fluid can be ensured by the fins 4. Thus, the heat exchange performance of the heat pipe 100b can be improved even more. In addition, a reduction in strength due to the formation of the thin wall portion 10a can be compensated for by the fins 4. Therefore, the heat pipe 100b can be operated more stably over a long period of time.

The second embodiment of the present disclosure has been described above. Note that various changes and modifications can be made to the above-described configurations without departing from the gist of the present disclosure. For example, the surface roughness of the fin 4 described above can be set to be greater than the surface roughness of the inside surface of the external cylinder 1. In other words, it is possible to employ a configuration in which fine irregularities are formed on the surface of the fin 4. According to this configuration, the area of contact between the fins 4 and the working fluid can be further enlarged. As a result, the heat exchange performance of the heat pipe 100b can be further improved.

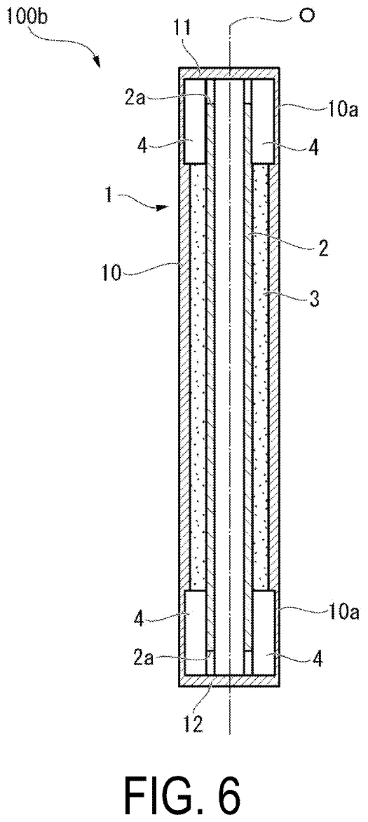

In the second embodiment described above, an example in which the fin 4 and the thin wall portion 10a are provided only at the end portion on the other side in the axis O direction has been described. However, the aspect of the fin 4 is not limited thereto, and as illustrated in FIG. 6, the fin 4 and the thin wall portion 10a can be also provided in the same manner at the end portion on the one side in the axis O direction (that is, the end portion on the side where the heat source is located). According to this configuration, the heat exchange performance of the heat pipe 100b can be improved even more.

Furthermore, in the second embodiment, an example in which the fins 4 are provided on the inner circumferential side of the external cylinder 1 has been described. However, it is also possible to employ a configuration in which the fins 4 are arranged along the outside surface of the external cylinder 1 in the circumferential direction. With such a configuration, the same effects as those described above can be obtained.

### Third Embodiment

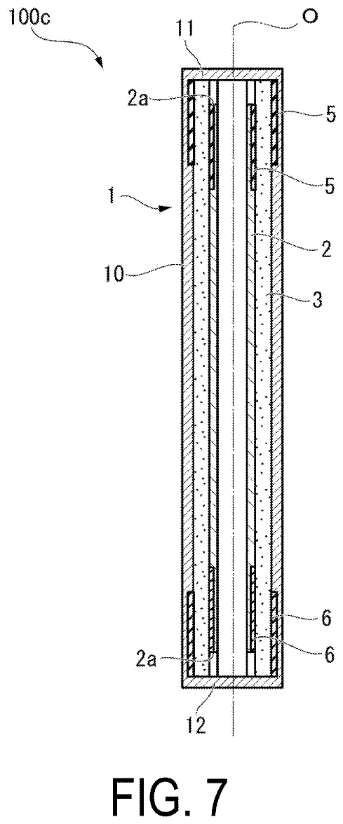

Next, a heat pipe 100c according to a third embodiment of the present disclosure will be described with reference to FIG. 7. The same components as those in each of the above-described embodiments will be denoted by the same reference signs, and a detailed description thereof will be omitted. As illustrated in FIG. 7, the heat pipe 100c according to the present embodiment further includes a hydrophilic portion 5 and a hydrophobic portion 6.

The hydrophilic portion 5 is provided in a region including the end portion on the inside surface of the external cylinder 1 and the end portion on the outside surface of the internal cylinder 2 on the one side in the axis O direction. The hydrophilic portion 5 is a thin film layer formed of, for example, a silane coupling material, and has relatively higher hydrophilicity than other portions.

The hydrophobic portion 6 is provided in a region including the end portion on the inside surface of the external cylinder 1 and the end portion on the outside surface of the internal cylinder 2 on the other side in the axis O direction. The hydrophobic portion 6 is a thin film layer formed of a silane coupling material, and has relatively higher hydrophobicity than other portions.

For example, a case where a heat source is provided on the one side in the axis O direction of the heat pipe 100c and a low temperature heat source is provided on the other side will be considered. According to the above configuration, because the hydrophilic portion 5 is provided in the region including the end portion on the one side in the axis O direction where the working fluid evaporates, the boiling limit on the surfaces of the external cylinder 1 and the internal cylinder 2 is relaxed, and the evaporation of the working fluid is further facilitated. Further, because hydrophobic portion 6 is provided in the region including the end portion on the other side in the axis O direction where the working fluid condenses, the condensation of the working fluid is further facilitated. As a result, the heat exchange performance of the heat pipe 100c can be further improved.

The third embodiment of the present disclosure has been described above. Note that various changes and modifications can be made to the above-described configurations without departing from the gist of the present disclosure. For example, in the third embodiment described above, an example in which the hydrophilic portion 5 and the hydrophobic portion 6 are formed of a silane coupling material has been described. However, the aspects of the hydrophilic portion 5 and the hydrophobic portion 6 are not limited thereto, and the hydrophilic portion 5 and the hydrophobic portion 6 can be formed by forming fine irregularities by direct machining of the surfaces of the external cylinder 1 and the internal cylinder 2.

### Fourth Embodiment

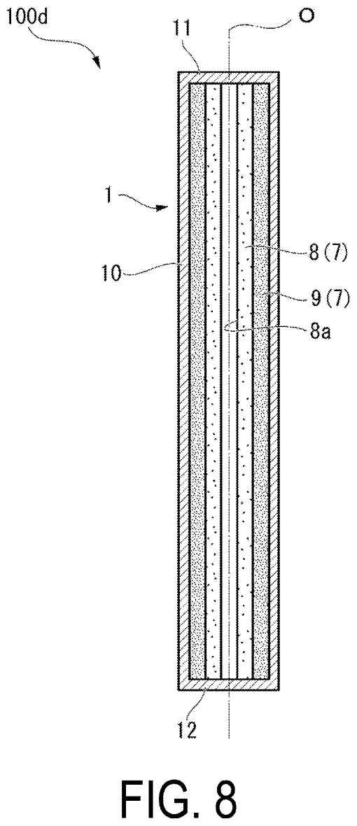

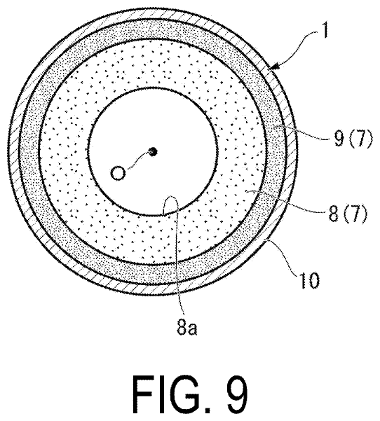

Next, a heat pipe 100d according to a fourth embodiment of the present disclosure will be described with reference to FIGS. 8 and 9. The same components as those in each of the above-described embodiments will be denoted by the same reference signs, and a detailed description thereof will be omitted. As illustrated in FIGS. 8 and 9, the heat pipe 100d according to the present embodiment includes an external cylinder 1 and a wick 7. The external cylinder 1 includes an external cylinder main body 10, a first lid body 11, and a second lid body 12 similar to those described in the first embodiment.

The wick 7 has a three dimensional lattice shape similar to that described in the first embodiment. A space as a gas passage flow path 8a extending through in the axis O direction is formed on the inner circumferential side of the wick 7. The wick 7 is formed of the same material as and integrally with the external cylinder 1 based on the AM method or the like.

Further, the wick 7 includes a gas-liquid passage portion 8 and a liquid passage portion 9. Specifically, the gas-liquid passage portion 8 is located on the inner circumferential side, and the liquid passage portion 9 is located on the outer circumferential side of the gas-liquid passage portion 8. Both of the gas-liquid passage portion 8 and the liquid passage portion 9 have a cylindrical shape centered around the axis O. The gas-liquid passage portion 8 has a void ratio (that is, the size of the three dimensional lattice) increasing from the outer side toward the inner side in the radial direction. On the other hand, the liquid passage portion 9 has a constant void ratio. Further, the void ratio (that is, the size of three dimensional lattice) of the liquid passage portion 9 is smaller than the void ratio of the gas-liquid passage portion 8. Furthermore, although not illustrated in detail, since the wick 7 also has a three dimensional lattice shape as in the first embodiment, the wick 7 includes a communicating portion for enabling communication between the gas-liquid passage portion 8 and the liquid passage portion 9 in the radial direction and the circumferential direction.

Inside the heat pipe 100d, in the cross section orthogonal to the axis O, the distribution amount of gas increases toward the inner circumferential side, and the distribution amount of liquid increases toward the outer circumferential side. The cross-sectional area of a flow path (void ratio) is preferably large in order to distribute a gas. On the other hand, the cross-sectional area (void ratio) of a flow path is preferably small in order to distribute a liquid by a capillary force. According to the above configuration, by setting a different void ratio for the gas-liquid passage portion 8 and the liquid passage portion 9, it is possible to optimize the cross-sectional area of a flow path depending on the distributions of a gas and a liquid. Consequently, the heat exchange performance of the heat pipe 100d can be further improved.

The fourth embodiment of the present disclosure has been described above. Note that various changes and modifications can be made to the above-described configurations without departing from the gist of the present disclosure. For example, the hydrophilic portion 5 and the hydrophobic portion 6 described in the third embodiment can be applied to the heat pipe 100d according to the fourth embodiment. Specifically, a configuration in which the hydrophilic portion 5 and the hydrophobic portion 6 are provided on the inside surface of the external cylinder 1 is conceivable. With such a configuration, the same effects as those described above can be obtained.

### Other Embodiments

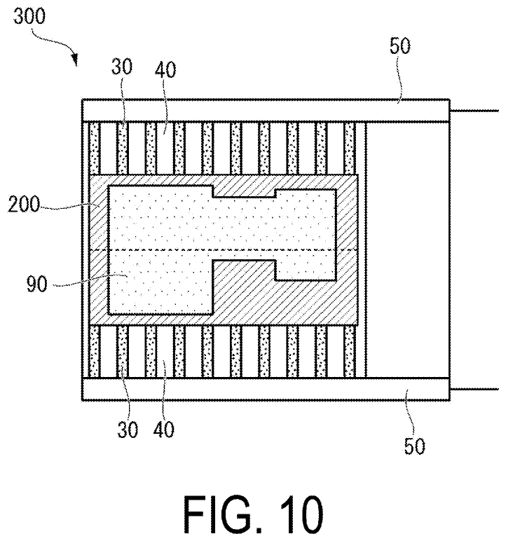

As illustrated in FIG. 10, the heat pipe 100, 100b, 100c, or 100d, or wick 3 or 7 described above can be used to cool a die-casting mold 300. The die-casting mold 300 includes a mold body 200, a wick 30, a steam flow path 40, and a cooling portion 50. The interior of the mold body 200 is filled with a molten metal material or the like (workpiece 90). A plurality of wicks 30 are arranged at intervals on the outer circumferential side of the mold body 200 so as to surround the mold body 200. Further, a space between the wicks 30 is configured to be the steam flow path 40. The wick 30 and the steam flow path 40 are in contact with the cooling portion 50. In other words, in this example, the wick 30 and the steam flow path 40 constitute the heat pipe 100, 100b, 100c or 100d described above. The mold body 200 corresponds to a heat source and the cooling portion 50 corresponds to a low temperature heat source. By employing such a configuration, the mold body 200 can be cooled faster and more stably.

### Notes

The heat pipe 100 according to each of the embodiments can be understood as follows, for example.

(1) A heat pipe 100 according to a first aspect includes an external cylinder 1 extending in an axis O direction, an internal cylinder 2 provided inside the external cylinder 1 so as to extend in the axis O direction, and a wick 3 provided between and integrally with the external cylinder 1 and the internal cylinder 2 and including a plurality of micro through portions 31 extending linearly in the axis O direction.

According to the above configuration, the micro through portion 31 extends linearly in the axis O direction, and thus the flow of a working fluid in the axis O direction can be generated more smoothly.

(2) In a heat pipe 100 according to a second aspect, the wick 3 has a three dimensional lattice shape and thus has a communicating portion 32 for enabling communication between the micro through portions 31 adjacent to each other.

According to the above configuration, the working fluid can move between the micro through portions 31 through the communicating portion 32. This allows the distribution of the working fluid in a cross section orthogonal to the axis O to be homogenized. As a result, the flow rate of the working fluid can be ensured, and the heat exchange performance can be improved.

(3) In a heat pipe 100 according to a third aspect, the plurality of micro through portions 31 are provided between the external cylinder 1 and the internal cylinder 2 in a radial direction with respect to the axis O.

According to the above configuration, the cross-sectional area of the flow path of the working fluid can be further increased. As a result, the heat exchange performance can be further improved.

(4) In a heat pipe 100b according to a fourth aspect, a thin wall portion 10a having a wall thickness smaller than a wall thickness of other portions of the external cylinder is formed in a region including at least one end portion of the external cylinder on one side in the axis O direction. A plurality of fins 4 protruding in a radial direction with respect to the axis O are provided at intervals in a circumferential direction on the thin wall portion 10a.

According to the above configuration, by forming the thin wall portion 10a, the thermal resistance between the working fluid and the outside is reduced. Further, a large area of contact with the working fluid can be ensured by the fins 4. As a result, the heat exchange performance can be further improved. In addition, a reduction in strength due to the formation of the thin wall portion 10a can be compensated for by the fins 4.

(5) In a heat pipe 100b according to a fifth aspect, a surface roughness of the fin 4 is set to be greater than a surface roughness of an inside surface of the external cylinder 1.

According to the above configuration, the area of contact between the fins 4 and the working fluid can be further enlarged.

(6) A heat pipe 100c according to a sixth aspect further includes a hydrophilic portion 5 and a hydrophobic portion 6. The hydrophilic portion 5 is provided in a region including an end portion on an inside surface of the external cylinder 1 and an end portion on an outside surface of the internal cylinder 2 on one side in the axis O direction and has relatively higher hydrophilicity than other portions. The hydrophobic portion 6 is provided in a region including an end portion on an inside surface of the external cylinder 1 and an end portion on an outside surface of the internal cylinder 2 on an other side in the axis O direction and has relatively higher hydrophobicity than other portions.

For example, a case where a heat source is provided on the one side in the axis O direction and a low temperature heat source is provided on the other side will be considered. According to the above configuration, because the hydrophilic portion 5 is provided in the region including the end portion on the one side in the axis O direction where the working fluid evaporates, the evaporation of the working fluid is further facilitated. Further, because hydrophobic portion 6 is provided in the region including the end portion on the other side in the axis O direction where the working fluid condenses, the condensation of the working fluid is further facilitated. As a result, the heat exchange performance can be further improved.

(7) A heat pipe 100d according to a seventh aspect includes an external cylinder 1 extending in an axis O direction, and a wick 7 being integrally provided on an inside surface of the external cylinder 1 inside the external cylinder 1 and forming a gas passage flow path 8a extending through along the axis O on an inner circumferential side. The wick 7 includes a gas-liquid passage portion 8 having a void ratio increasing from an outer side toward an inner side in a radial direction of the axis O.

Inside the heat pipe 100d, in the cross section orthogonal to the axis O, the distribution amount of gas increases toward the inner circumferential side, and the distribution amount of liquid increases toward the outer circumferential side. The cross-sectional area of a flow path (void ratio) is preferably large in order to distribute a gas. On the other hand, the cross-sectional area (void ratio) of a flow path is preferably small in order to distribute a liquid by a capillary force. According to the above configuration, it is possible to optimize the cross-sectional area of a flow path depending on the distributions of a gas and a liquid. As a result, the heat exchange performance can be further improved.

(8) In a heat pipe 100d according to an eighth aspect, the wick 7 further includes a liquid passage portion 9 provided on an outer circumferential side of the gas-liquid passage portion 8 and having a void ratio smaller than a void ratio of the gas-liquid passage portion 8.

According to the above configuration, by providing the liquid passage portion 9, the working fluid as a liquid can move more smoothly.

(9) In a heat pipe 100d according to a ninth aspect, the wick 7 has a three dimensional lattice shape and thus has a communicating portion for enabling communication between the gas-liquid passage portions 8 adjacent to each other and between the liquid passage portions 9 adjacent to each other.

According to the above configuration, the working fluid can move through the communicating portion in a cross section orthogonal to the axis O. This allows the distribution of the working fluid in the cross section to be homogenized. As a result, the flow rate of the working fluid can be ensured, and the heat exchange performance can be improved.

(10) A heat pipe 100d according to a tenth aspect further includes a hydrophilic portion 5 and a hydrophobic portion 6. The hydrophilic portion 5 is provided in a region including an end portion on an inside surface of the external cylinder 1 on one side in the axis O direction and has relatively higher hydrophilicity than other portions. The hydrophobic portion 6 is provided in a region including an end portion on an inside surface of the external cylinder 1 on an other side in the axis O direction and has relatively higher hydrophobicity than other portions.

For example, a case where a heat source is provided on the one side in the axis O direction and a low temperature heat source is provided on the other side will be considered. According to the above configuration, because the hydrophilic portion 5 is provided in the region including the end portion on the one side in the axis O direction where the working fluid evaporates, the evaporation of the working fluid is further facilitated. Further, because hydrophobic portion 6 is provided in the region including the end portion on the other side in the axis O direction where the working fluid condenses, the condensation of the working fluid is further facilitated. As a result, the heat exchange performance can be further improved.

While preferred embodiments of the invention have been described as above, it is to be understood that variations and modifications will be apparent to those skilled in the art without departing from the scope and spirit of the invention. The scope of the invention, therefore, is to be determined solely by the following claims.

1. A heat pipe comprising:
an external cylinder extending in a direction of an axis line;
an internal cylinder provided inside the external cylinder so as to extend in the direction of the axis line; and
a wick provided between and integrally with the external cylinder and the internal cylinder, the wick including a plurality of micro through portions extending linearly in the direction of the axis line.

2. The heat pipe according to claim 1, wherein the wick has a three dimensional lattice shape and thus has a communicating portion for enabling communication between the micro through portions adjacent to each other.

3. The heat pipe according to claim 1, wherein the plurality of micro through portions are provided between the external cylinder and the internal cylinder in a radial direction with respect to the axis line.

4. The heat pipe according to claim 1, wherein
a thin wall portion having a wall thickness smaller than a wall thickness of other portions of the external cylinder is formed in a region including at least one end portion of the external cylinder on one side in the direction of the axis line, and
a plurality of fins protruding in a radial direction with respect to the axis line are provided at intervals in a circumferential direction on the thin wall portion.

5. The heat pipe according to claim 4, wherein a surface roughness of each of the plurality of fins is set to be greater than a surface roughness of an inside surface of the external cylinder.

6. The heat pipe according to claim 1, further comprising:
a hydrophilic portion provided in a region including an end portion on an inside surface of the external cylinder and an end portion on an outside surface of the internal cylinder on one side in the direction of the axis line, the hydrophilic portion having relatively higher hydrophilicity than other portions; and
a hydrophobic portion provided in a region including an end portion on an inside surface of the external cylinder and an end portion on an outside surface of the internal cylinder on an other side in the direction of the axis line, the hydrophobic portion having relatively higher hydrophobicity than other portions.

7. A heat pipe comprising:
an external cylinder extending in a direction of an axis line; and
a wick being integrally provided on an inside surface of the external cylinder inside the external cylinder, the wick forming a gas passage flow path extending through along the axis line on an inner circumferential side,
the wick including a gas-liquid passage portion having a void ratio increasing from an outer side toward an inner side in a radial direction of the axis line.

8. The heat pipe according to claim 7, wherein the wick further comprises a liquid passage portion provided on an outer circumferential side of the gas-liquid passage portion and having a void ratio smaller than a void ratio of the gas-liquid passage portion.

9. The heat pipe according to claim 8, wherein the wick has a three dimensional lattice shape and thus has a communicating portion for enabling communication between the gas-liquid passage portions adjacent to each other and between the liquid passage portions adjacent to each other.

10. The heat pipe according to claim 7, further comprising:
a hydrophilic portion provided in a region including an end portion on an inside surface of the external cylinder on one side in the direction of the axis line, the hydrophilic portion having relatively higher hydrophilicity than other portions; and
a hydrophobic portion provided in a region including an end portion on an inside surface of the external cylinder on an other side in the direction of the axis line, the hydrophobic portion having relatively higher hydrophobicity than other portions.
